(19) United States
(12) Patent Application Publication
(10) Pub. No.: US 2017/0168975 A1
(43) Pub. Date: Jun. 15, 2017

(54) Modular Computer System, Server Module and Rack Arrangement

(71) Applicant: FUJITSU LIMITED, Kawasaki-shi (JP)

(72) Inventor: Hans-Jürgen Heinrichs, Altenbeken (DE)

(73) Assignee: FUJITSU LIMITED, Kawasaki-shi (JP)

(21) Appl. No.: 15/445,068

(22) Filed: Feb. 28, 2017

Related U.S. Application Data
(63) Continuation of application No. PCT/EP2015/069955, filed on Sep. 1, 2015.

(30) Foreign Application Priority Data
Sep. 9, 2014 (DE) 102014112942.3

(51) Int. Cl. G06F 13/40; H05K 7/14; G06F 13/36

(52) U.S. Cl. CPC G06F 13/409; G06F 13/36; G06F 13/4068; H05K 7/1492

(57) ABSTRACT

A modular computer system includes a chassis with receiving bays, arranged in the region of a first housing side, for the reception of corresponding functional modules. Furthermore, the modular computer system includes at least one first control panel arranged on a second housing side and having control elements. The at least one control panel is coupled to connections of a first receiving bay and of a second receiving bay. At least one first subgroup of the control elements is assigned to the first receiving bay and a second subgroup of the control elements is assigned to the second receiving bay. The modular computer system is configured to transmit module-specific control data between the first subgroup of the control elements and a functional module received in the first receiving bay and between the second subgroup of the control elements and a functional module received in the second receiving bay.

The invention relates to a modular computer system, comprising a chassis having a plurality of receiving bays for receiving corresponding functional modules, in particular server modules. The invention furthermore relates to a server module for a modular computer system and a rack arrangement with at least one modular computer system received in the rack housing as a rack plugin.

With the growing demand for IT services worldwide, the demand for computing performance continues to increase. Here, besides the mere provision of computing power, the associated space and energy needs also play an important role. This relates to relatively small server arrangements, such as those found in IT departments of small and medium-sized enterprises, for example, as well as computing centers of large companies or specialized providers of IT services.

In order to be able to expand computing performance in accordance with requirements, various approaches to the structure of expandable computer systems are known from the prior art. A relatively simple approach is to integrate server computers into server racks with a standard form factor, typically a 19-inch rack plugin, and to add further server computers to respective server racks as required. The individual server computers work in a relatively independent manner. In particular, such server computers have individual power supplies and network interfaces. Such systems are comparatively inexpensive, but require a relatively large amount of space and administration.

An alternative approach is the integration of individual, so-called blade servers into a blade server system. A blade system, besides the actual blade servers with the processors and main memories arranged thereon, comprises a number of infrastructure components, such as power supplies, network switches, network interfaces and mass storage units, which are accessed as shared resources by the individual blade servers. In addition, each blade system typically comprises one or more so-called management blades, which is used to monitor, manage and administer the remaining components. Blade server systems enable high performance computing, but are relatively expensive. This is due, among other things, to the plurality of special components required to build a functional blade server system.

In a third approach, which is referred to, inter alia, as a modular computer system or as a multi-node computer system, a plurality of server modules are received in a common chassis. Since the server modules do not have a separate housing, they are partially referred to as “skinless” servers. The individual server modules can be connected via the chassis with a common power supply, cooling and similar simple or standardized components such as hard disk drives, wherein the server modules per se represent largely independent server computers.

In particular, such modular computer systems do not require a central administration instance, as is customary, for example, in blade server systems. They allow a high-performance computing at relatively low costs of the overall system.

A modular computer system of the type described above is known for example from the international application WO 2013/068250 A1. The server system disclosed there comprises at least one circuit board arranged in the chassis for contacting server plugins received in plugin bays, wherein the circuit board has at least one first microcontroller. The server system comprises furthermore a first server plugin, which is arranged in the first plugin bay and is coupled to the at least one circuit board, wherein the first server plugin has a first system management controller. Here, the first microcontroller and the first system management controller are coupled to one another via at least one first signal line and the first microcontroller is configured to provide at least one chassis-specific configuration value to the system management controller. This arrangement makes it in particular possible to indirectly access chassis-specific configuration data of the server system via a network and a system management controller of an individual server plugin without the chassis itself having a network interface.

In such computer systems, there is a challenge to simplify or improve the use of system components provided via the chassis to improve integration of the modular computer system. At the same time, the structure of the chassis per se or the components installed therein should be kept as simple as possible in order to limit their price and complexity.

Against this background, the present application describes a modular computer system comprising a chassis with a plurality of receiving bays, arranged in the region of a first housing side, for receiving corresponding functional modules, in particular server modules. The modular server system comprises at least one first operator panel arranged on a second housing side, having a plurality of operating elements. The at least one operator panel is coupled to a first connection of a first receiving bay and to a second connection of a second receiving bay via at least one first serial bus system. At least one first subgroup of the operating elements is assigned to the first receiving bay and a second subgroup of the operating elements is assigned to the second receiving bay. Here, the modular computer system is configured to transmit module-specific control data via the first serial bus system between the first subgroup of the operating elements and a functional module received in the first receiving bay and between the second subgroup of the operating elements and a functional module received in the second receiving bay.

By using a serial bus system for connecting function modules received in individual receiving bays and associated sub-groups of operating elements of a operator panel arranged on the modular computer system, the number of signal lines required can be reduced in comparison with known approaches. In addition to the reduction of signal lines as such, this also has the advantage, inter alia, that a larger number of functional modules can be received in a modular computer system without that lines required for the connection thereof affect a cooling of the modular computer system or increase the complexity of connecting elements.

According to one embodiment of the invention, at least one microcontroller is arranged in the chassis which is configured to subsequently exchange module-specific control data with functional modules received in different receiving bays via the serial bus system. By providing a microcontroller in the chassis, an ordered exchange of module-specific control data via the serial bus system can be ensured. Thereby bus collisions are avoided, so that a predetermined temporal sequence is ensured during the exchange of the control data.

In at least one embodiment, the modular computer system comprises two operator panels, each of which is connected to the microcomputer via its own serial bus system. By providing different serial bus systems, data traffic from and to the functional modules on the one hand and from and to the operator panels on the other hand is separated.

In at least one embodiment, the microcontroller, the connections assigned to the receiving bays and/or the at least one serial bus system are arranged on at least one circuit board in the interior of the chassis. When arranging the corresponding components on a circuit board located in the chassis, in particular a so-called midplane, the provision of individual cables for connecting the operating modules is largely unnecessary.

According to at least one embodiment, the microcontroller is furthermore connected to at least one administrative component of the modular computer system via at least one system management bus. Here, the at least one operator panel has at least one system-specific operating element assigned to the modular computer system as a whole and the microcontroller is configured to exchange and buffer system-specific control data via the system management bus with the at least one administrative components, and to exchange it with the system-specific operating element. By means of the features mentioned, besides the module-specific control data, system-specific control data can also be displayed or accepted via the operator panel.

The operating elements of the operator panel can be switching elements, such as, for example, buttons, whose switching states can be verified and forwarded to the individual functional modules. Alternatively, or additionally, the operating elements are display elements, such as, for example, light-emitting diodes, which can indicate the state of the individual functional modules.

According to a further aspect of the invention, a server module for use in a modular computer system, in particular the computer system described above, is described. The server module has at least one system board for receiving system components, at least one module connection for electrically contacting a corresponding connection of the modular computer system, and at least one input/output module having a plurality of parallel input/output connections as well as a bus connection for a serial bus system. In this case, the bus connection of the input/output module is electrically connected to the module connection, the parallel input/output connections are connected to module specific control signals and the input/output module is configured to transmit the control signals received or output via the parallel input/output connections as module-specific control data via the serial bus system.

By providing an input/output module with a plurality of parallel input/output connections on a system board of a server module, control signals which typically occur in a server module can be sent and/or received from there without further adaptation in a simple manner via a serial bus connection to an operator panel separated from the server module, in particular without adaptation of the firmware of the server module.

In at least one embodiment, the modular server system with server modules received therein is suitable for reception in a rack arrangement. Here, the at least one operator panel is arranged in a region of the modular computer system which is accessible from the first side of the rack housing and is used for fastening the modular computer system to the rack housing. Such an arrangement serves to improve the utilization of the available space of the front side of the modular server system.

Further advantageous embodiments are disclosed in the appended claims as well as in the following detailed description of an exemplary embodiment.

The invention is described in detail hereinafter regarding an exemplary modular computer system with reference to the attached figures. In the figures and the description, individual instances of similar components are distinguished from one another by an alphabetical suffix. If no suffix is specified, all components are referred to respectively. The figures show in:

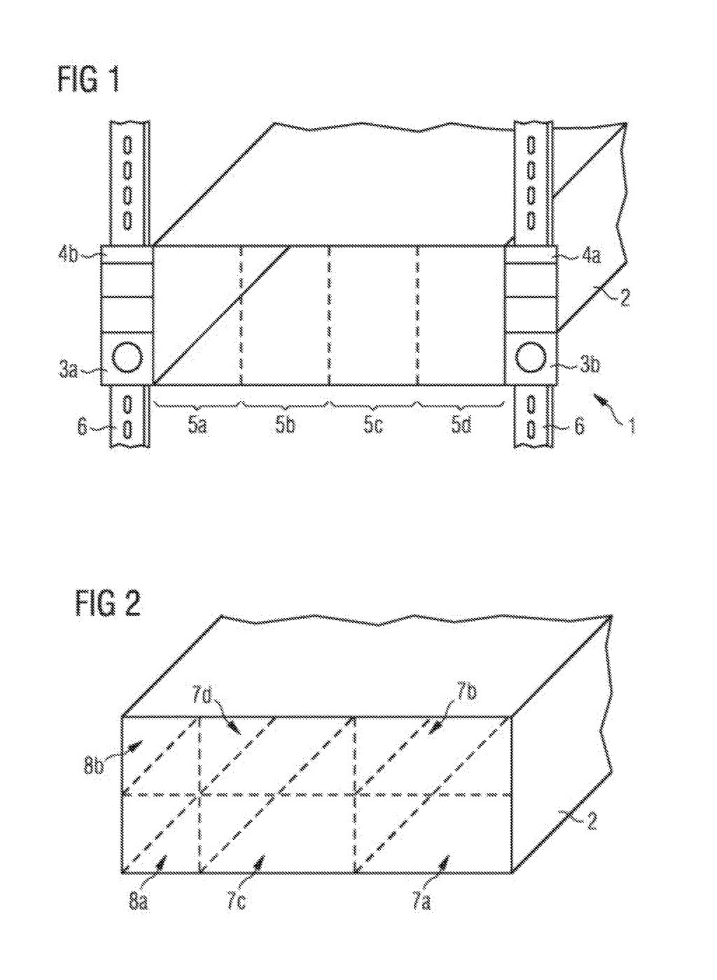

FIG. 1 a perspective front view of a chassis of a modular computer system,

FIG. 2 a perspective rear view of the chassis according to FIG. 1,

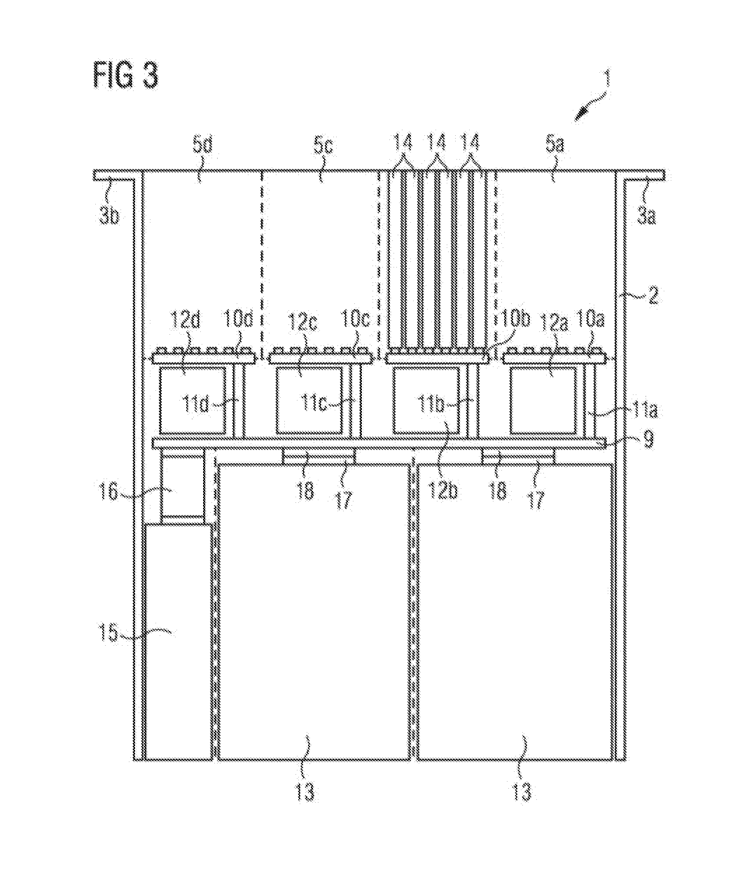

FIG. 3 a schematic illustration of the system structure of the modular computer system,

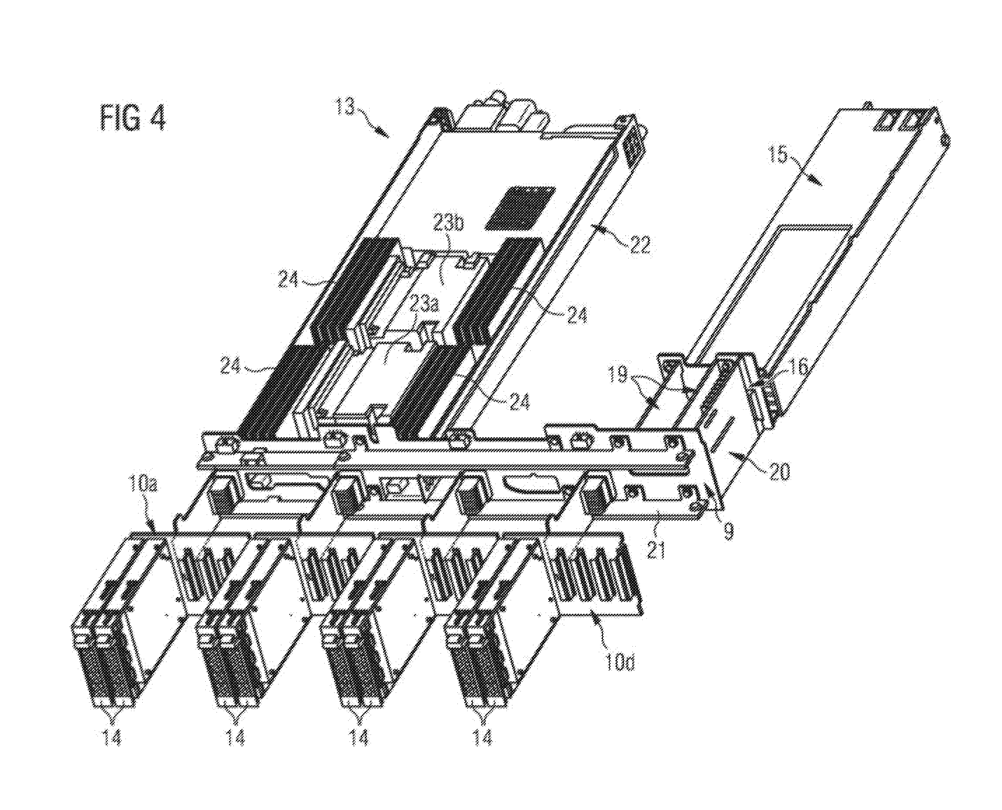

FIG. 4 a perspective view of different functional units of the modular computer system,

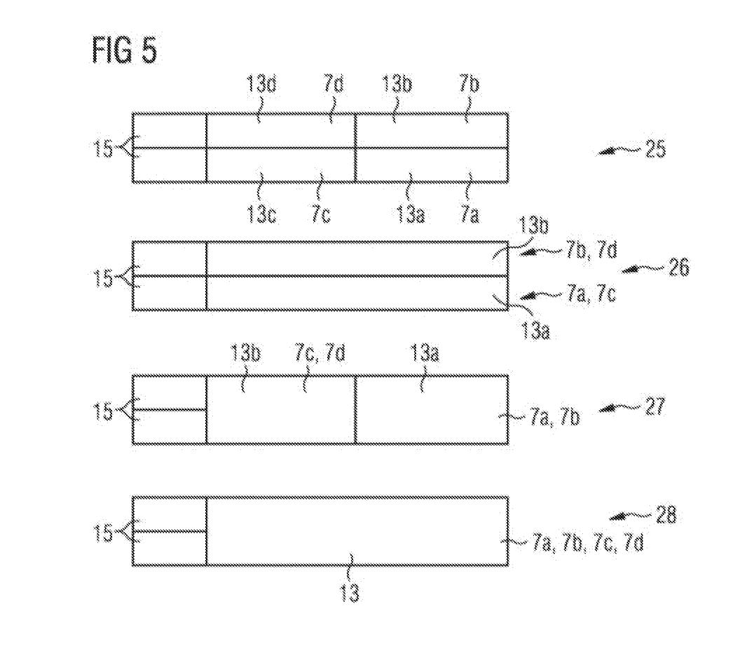

FIG. 5 a schematic illustration of different configurations of the modular computer system,

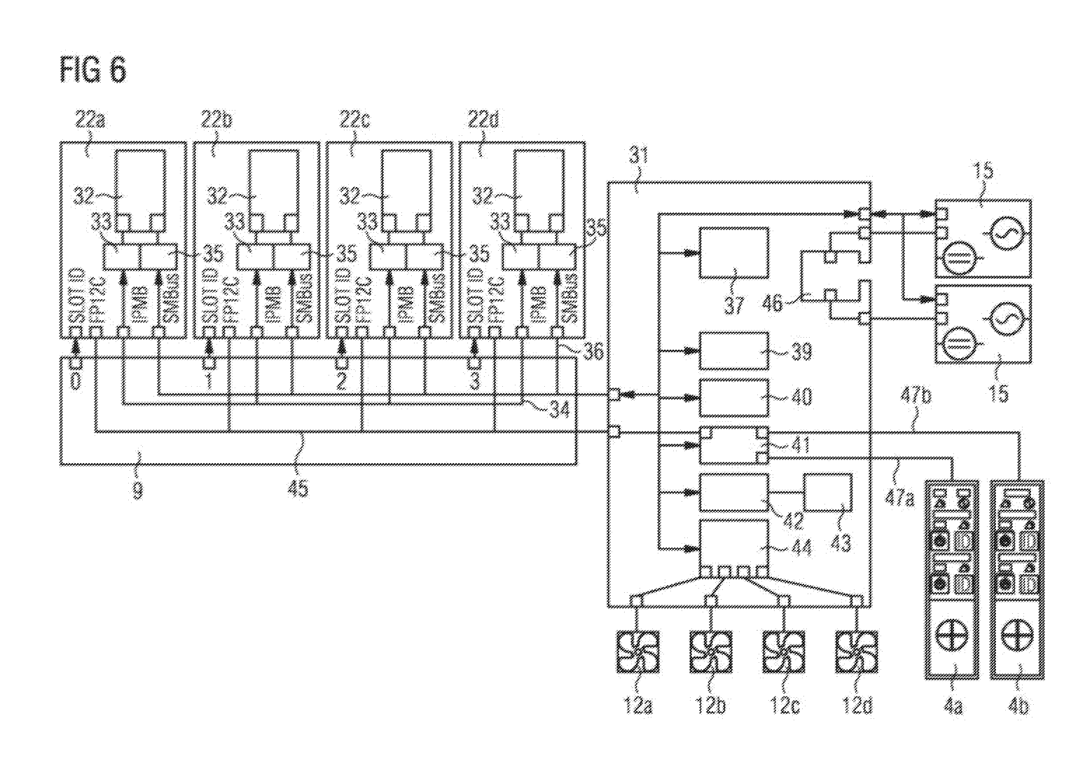

FIG. 6 a schematic illustration of the connection of functional modules with components of the chassis,

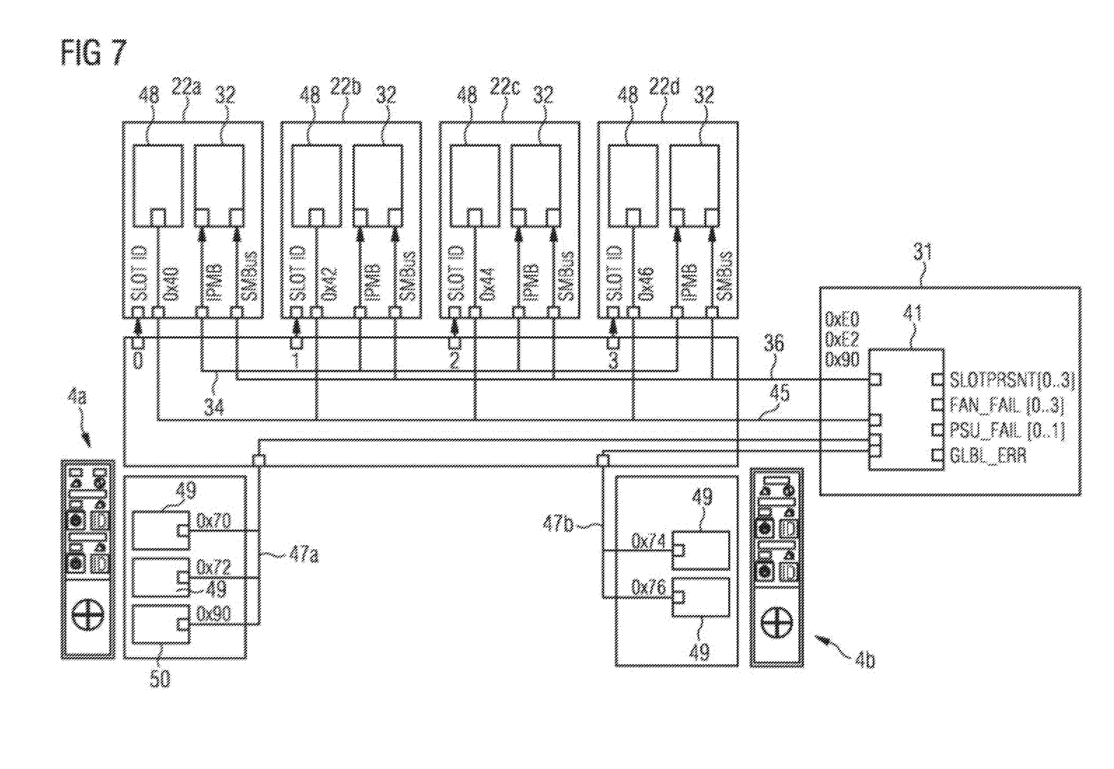

FIG. 7 a schematic illustration of the connections of functional modules with two operator panels,

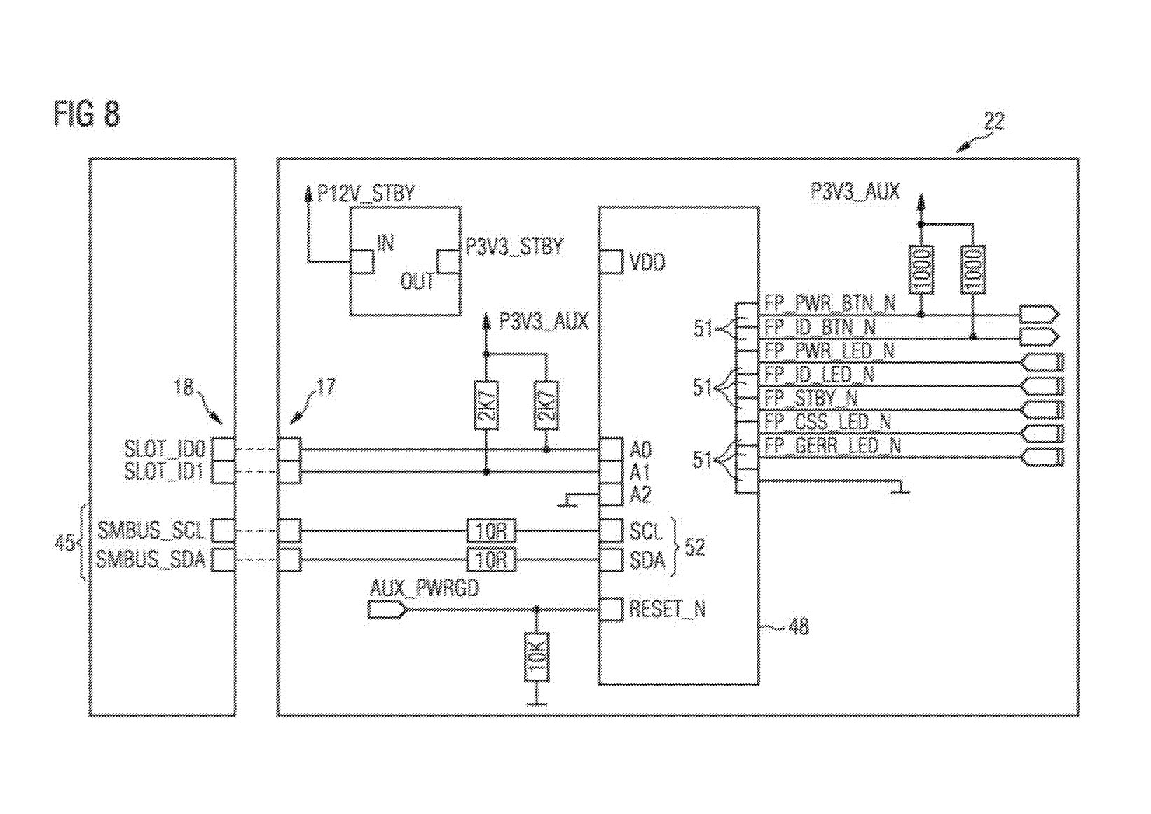

FIG. 8 an electric connection plan for connecting a server module to a serial bus system,

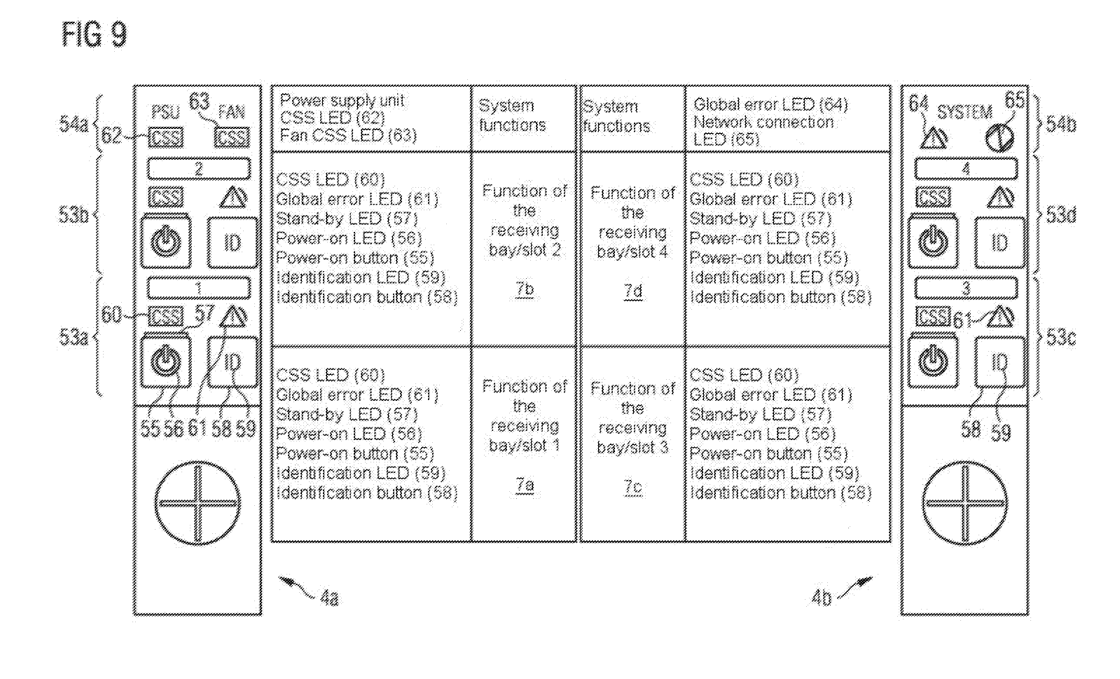

FIG. 9 a detailed illustration of the two operator panels with corresponding functions and

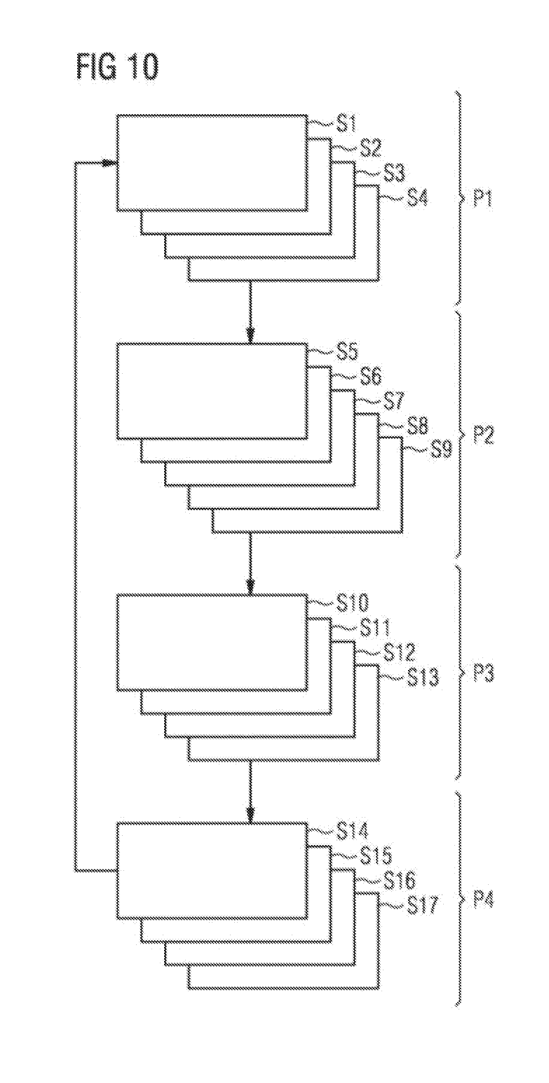

FIG. 10 a flow chart of a method for exchanging control data

Before going into details of the solution according to the invention, first the general system design of a modular computer system using FIGS. 1 to 5 according to the exemplary embodiment used will be described. The described computer system is a so-called multi-node system, in which multiple server modules operating logically largely independently of one another are arranged in a common chassis.

FIG. 1 shows a perspective front view of a chassis 2 for such a modular computer system 1. In the exemplary embodiment chassis 2 corresponds to a standard size, in particular to a 19-inch rack format for plugin into a corresponding rack housing. For this purpose, the chassis 2 has, in the region of a front side, two fastening straps 3a and 3b with which the chassis 2 is fastened to vertical perforated rails 6 of the rack housing, which is not shown. For fastening, for example, thumb screws or other fastening means known per se are used. The chassis 2 according to FIG. 1 has a construction height of two so-called high units of 44.45 millimeters each. It is, of course, also possible to use other structural heights for receiving larger or other components than the components described hereinafter.

In order to make optimum use of the available area which can be reached from the front side of the rack housing, operator panels 4a and 4b are arranged on the fastening straps 3a and 3b, respectively, which display different control data or are used to input control data. The space available between the operator panels 4a and 4b is used, in the exemplary embodiment, to receive memory plugins in a standard format, in particular hard disk modules. In the exemplary embodiment shown, a total of 24 hard disk modules with hard disk drives in the 2.5-inch format, which are divided into four groups 5a to 5d of memory plugins, can be arranged in the central area.

The described modular computer system 1 serves to receive up to four individual functional modules, in particular server modules, in corresponding receiving bays 7a to 7d. The functional modules are plugged in into the chassis 2 from a rear side shown in FIG. 2. Although the individual receiving bays 7a to 7d are shown separated by dashed lines in FIG. 2, it is pointed out that a physical separation in the chassis 2 is not required. This way, in particular larger function modules can be received in neighboring receiving bays 7a to 7d, as described below according to FIG. 5. In a side region of the rear side, the chassis 2 has two further receiving bays 8a and 8b for receiving two corresponding power supply units. These receiving bays are also not physically separated from each other.

FIG. 3 shows a schematic top view on the system structure of the modular computer system 1. It can be seen therein that further components are arranged in the interior of the chassis 2 besides the aforementioned components. In particular, the chassis 2 comprises a first circuit board 9 which is arranged perpendicular to the plugin direction of the functional modules 13. The first circuit board 9 is also partially referred to as midplane since it is arranged inside a housing and can be contacted from two sides by further components. The individual functional modules 13 and other components of the modular computer system 1 are connected to one another via the first circuit board 9. For electrical contacting, each of the functional modules 13 has a module connection 17, which can be plugged into a corresponding connection 18 of the first circuit board 9.

Furthermore, in the exemplary embodiment, the modular computer system 1 comprises four second circuit boards 10a to 10d which are each assigned to one of the groups 5a to 5d of memory plugins 14. Via the second printed circuit boards 10a to 10d, a group 5 of six memory plugins 14, for example via standardized SAS or SATA plug connectors, can be contacted. The four second circuit boards 10a to 10d are connected to the first circuit board 9 via four corresponding circuit board connectors 11a to 11d. In the case of the circuit board connectors 11a to 11d per se, it can be circuit boards with corresponding plug connectors.

Between the first circuit board 9 and the second circuit boards 10a to 10d, four cooling devices 12a to 12d are arranged in the exemplary embodiment. The cooling devices 12a to 12d are, in each case, double-fan systems, with two axially arranged single fans. The cooling devices 12a to 12d suck air from the front through the groups 5a to 5d of memory plugins 14 and blow it out of the chassis 2 via the functional modules 13 and power supplies 15 plugged into the receiving bays 7a to 7d.

Finally, it can be seen in FIG. 3 that the power supplies 15 do not extend over the entire depth between the rear side of the chassis 2 and the first circuit board 9. For electrically contacting, a connection structure 16 is therefore arranged between the power supplies 15 and the first circuit board 9, which is in particular suitable for the transmission of large currents.

FIG. 4 shows a perspective view of the various system components of the modular computer system 1 without the associated chassis 2.

In the illustration according to FIG. 4, the structure of the connection structure 16 can be seen in detail. Besides two copper plates 19, the connecting structure 16 also has a third printed circuit board 20 which connects control components of the power supplies 15 to other system components of the modular computer system 1 via a system management bus which cannot be seen in the figure. In the exemplary embodiment, copper rails 21 are arranged on the rear side of the circuit board 9 in order to transmit the electrical energy transmitted via the connection structure 16 from the power supplies to the functional modules 13 received in the receiving bays 7a to 7d.

The first circuit board 9 as well as the second circuit boards 10a to 10d each have openings, in addition to the connections required for the connection of the different functional modules 13 or memory plugins 14, which enable ventilation of the components installed in the chassis 2.

Furthermore, it can be seen that in the illustrated exemplary embodiment, the functional module 13 is configured as a server module 22. In the exemplary embodiment, the server module 22 has a system board concealed in FIG. 4 as well as two processors 23a and 23b arranged thereon, with a total of four assigned memory banks 24. On the rear side of the server module 22, various plug connectors, for example for connecting the server module 22 to a local data network, are provided.

FIG. 5 schematically shows different possibilities for implementing the modular computer system 1 with functional modules 13. In a first configuration 25, each of the receiving bays 7a to 7d is equipped with its own functional module 13a to 13d, for example a server module 22. In a second configuration 26, only two functional modules 13a and 13b each of double width are arranged in two neighboring receiving bays 7a and 7c or 7b and 7d, respectively. In a third configuration 27, two function modules 13a and 13b having a double structural height are arranged in two receiving bays 7a and 7b or 7c and 7d, respectively placed above. This configuration is particularly flexible because, for example, a server module 22 with a single structural height can be combined with a supplementary module placed above, for example a high-performance computing module with one or more graphics processors. Finally, FIG. 5 shows a fourth configuration 28 in which only a single functional module 13 with a double width and double height fills all the receiving bays 7a to 7d.

The connection of the individual functional modules 13 with further components of the chassis 2 is described in detail hereinafter. At this point, it is pointed out that the functional modules 13, in particular in the form of server modules 22, operate largely independently of one another. In particular, each of the functional modules 13 is connected to its own corresponding group 5 of memory plugins. For communication to the outside, each of the functional modules 13 utilizes a network or other communication interface of their own. Correspondingly, standard components can be used extensively for the construction of the individual functional modules 13. In the embodiment as server modules 22, for example, each of the functional modules 13 comprises a circuit board which is designed as a system board and has components arranged thereupon, such as, for example, processors 23 and memory banks 24. System administration generally takes place via a data network and a system management module of the individual server modules 22. For the system integration of the modular computer system 1, a standard-conform connection of the individual functional modules 13 is therefore significant.

FIG. 6 shows schematically the connection of four server modules 22a to 22d with the various components of the chassis 2. As can be seen from FIG. 6, each of the server modules 22a to 22d is connected to the respective other server modules 22a to 22d or to a chassis interface unit 31 via three bus systems 34,36 and 45.

In particular, so-called system management modules 32, also known as “intelligent remote management controllers” (iRMC), of server modules 22 are connected via a first interface module 33 to a so-called IPMB bus 34 for communication with neighboring server modules 22. Furthermore, the system management modules 32 are connected to different components of the chassis interface unit 31 via a second interface module 35 and a serial system management bus 36. In particular, the system management bus 36 for connecting the system management modules 32 to control units of the power supply units 15, which is not shown in FIG. 6, serves as an ambient temperature sensor 37, a so-called chassis FRU memory 39 for storing a chassis identifier, a capacitor-buffered light path controller 40 for storing and displaying error states via so-called “Customer Self Service” (CSS) light-emitting diodes, a first microcontroller 41 for exchange of control data via the operator panels 4a and 4b, a second microcontroller 42 for connecting a flash memory 43 as well as a third microcontroller 44 for controlling the cooling devices 12a to 12d. In addition to the system management bus 36, the server modules 22a to 22d are also connected to the first microcontroller 41 for connecting to the operator panels 4a and 4b, independently of the system management modules 32 via a further serial bus system 45. Each of the operator panels 4a and 4b is connected to the first microcontroller 41 via its own further serial bus system 47a and 47b.

In the exemplary embodiment, the bus systems 34, 36, 45, 47a and 47b are each configured as serial bus systems. It should be pointed out that the various serial bus systems 34, 36, 45, 47a and 47b each require only a relatively small number of signal lines of the components connected thereto. Thus, only relatively few lines have be provided on the first circuit board 9, which in particular improves the ventilation and thus cooling of the modular computer system 1.

Parallel accesses by different functional modules 13 to the bus systems 34, 36 and 45 are avoided using methods intrinsic to the bus. In the case of the IPMB bus system 34 as well as the system management bus 36, the bus masters, such as the system management modules 32, monitor, according to the I2C protocol, whether bus lines are already driven by another bus user while they per se are transmitting data. If such a collision is detected, the detecting bus user waits for a predetermined period of time before a transaction is restarted. This ensures that respectively only one transaction takes place on the system management bus 36. The first microcontroller 41 is the only bus master for the serial bus systems 45, 47a and 47b, so that no conflicts arise.

Finally, it can be seen in FIG. 6 that the two power supplies 15 are connected to one another via a dedicated control circuit 46. The control circuit 46 permits inter alia a monitoring of the secondary direct supply voltage, as well as a primary alternating net voltage provided by the power supplies 15, independent of the system management bus 36. The control circuit 46 also requires only a few control lines for connection to the power supplies 15. For example, each of the power supplies 15 has a control line for signaling a disturbance of the primary supply voltage, a control line for signaling a stable secondary supply voltage, and a third control line for switching on the respective power supply 15. The different control lines are evaluated by the control circuit 46 by means of of a discrete circuit and are forwarded to the individual server modules 22 or are verified by the server modules 22, combined and forwarded to the power supplies 15.

FIG. 7 shows in detail the connection of the individual server modules 22a to 22d respectively to the operator panels 4a and 4b. For the sake of clarity, the illustration of further components in the chassis 2, which are not important for the control of the operator panels 4a and 4b, was omitted.

As can be seen in FIG. 7, each of the server modules 22 has an input/output module 48, via which various control signals can be evaluated and transmitted as serially transmitted control data via the serial bus system 45 to the first microcontroller 41. These control signals partly derive from the system management module 32, but can also be provided by other system components of the server modules 22. This approach makes it possible in particular to dispense with an adaptation of the firmware of the server modules 22. Control signals occurring in the individual server modules 22 are buffered in hardware by the input/output modules 48, combined to form module-specific control data and transmitted transparently via the serial bus system 45 to the microcontroller 41 for the firmware of the individual server modules 22.

For this purpose, the microcontroller 41 successively verifies the individual input/output modules 48 of the server modules 22, as described hereinafter regarding FIG. 10. The verified control data are buffered by the microcontroller 41 and are transmitted via the serial bus systems 47a and 47b to the first operator panel 4a and the second operator panel 4b, respectively.

For the operator panels 4a and 4b, in each case a further circuit board with in each case two input/output modules 49 arranged thereupon is provided. The circuit boards of the operator panels 4a and 4b are each connected to the first circuit board 9 via a multi-conductor cable connection. The input/output modules 49 convert the serially transmitted control data back into individual control signals for individual operating elements of the operator panels 4a or 4b assigned to the respective control signals. In the reverse direction, inputs made by operating elements of the operator panels 4a and 4b, such as, in particular, button pressures, can be verified by the first microcontroller 41 via the input/output modules 49 and the serial bus systems 47a and 47b. The verified control data are then assigned to the individual server modules 22a to 22d by the microcontroller 41 and are transmitted as corresponding serial control data via the first serial bus system 45 back to the input/output modules of the server modules 22a to 22d.

FIG. 7 shows that a temperature sensor 50 is additionally arranged on the first operator panel 4a on the left in the exemplary embodiment. The data of the temperature sensor 50 are also fetched from the first microcontroller 41 via the serial bus system 47a and made available to other components of the modular computer system 1 via the system management bus modular computer system 1 via the system management bus.

FIG. 8 shows an electrical connection plan for the connection of the input/output module 48 of a server module 22 via a serial bus connection 52 to the serial bus system 45. As can be seen in FIG. 8, the input/output module 48 has eight freely configurable input/output connections 51. Data received from the input/output connections 51 can be combined into control data sets for serial transmission. Reversely, serial control data sets transmitted by the serial bus system 45 can be output via appropriately configured input/output connections 51 for output. As can be seen from FIG. 8, a bus connection 52 of the input/output module 48 is a connection for a two-wire bus system according to the I²C standard.

In the described exemplary embodiment, the input/output module 48 also serves to recognize the number of the receiving bay 6 into which a server module 22 is plugged. In the exemplary embodiment, corresponding connection pins of a connection 18 of the first circuit board 9 have hard-coded signal levels which can be verified via the module connection 17 from the input/output module 48.

FIG. 9 shows in detail the operating elements assigned to the first operator panel 4a on the left in the exemplary embodiment, and the operating elements assigned to the second operator panel 4b assigned to the exemplary embodiment. It can be seen here that each of the operator panels 4a and 4b has respectively two sub-groups 53a and 53b or 53c and 53d of operating elements, which are assigned to corresponding receiving bays 7a and 7b and 7c and 7d and has another subgroup 54a or 54b of operating elements, that is assigned to the modular computer system 1 as a whole. In particular, each of the receiving bays 7 for receiving a server module 22 is assigned with a power-on button 55, a corresponding power-on LED 56 and stand-by LED 57, an identification button 58 and a corresponding identification LED 59, as well as two further LED displays 60 and 61 for displaying CSS Control codes or global error states. In the exemplary embodiment, these operating elements are present four times, for the four receiving bays 7a to 7d, wherein the operating elements for the receiving bays 7a and 7b are arranged on the left operator panel 4a and the operating elements for the receiving bays 7c and 7d on the right operator panel 4b. Furthermore, two further LED displays 62 and 63 for displaying system-specific states are provided on the first operator panel 4a. In particular, an LED for a CSS state code of the power supplies 15 and/or the cooling devices 12a to 12d is provided in each case. For example, it can be displayed via the LED display 63 that a fan has failed and has to be replaced. Finally, two further system-specific display elements are arranged on the second operator panel 4b. A first LED display 64 is used to display a global error state. A second LED display 65 is used to display a connection of the chassis 2 to an alternating net voltage.

FIG. 10 shows a flow chart of a control software executed by the first microcontroller 41. In a first phase P1, the states of control signals of the server modules 22a to 22d, which are to be displayed via corresponding display elements of the operator panels 4a and 4b, are verified in steps S1 to S4. In particular, the state of the power-on LED 56, the stand-by LED 57, the identification LED 59, the CSS-LED 61 and the error LED 61 are verified together in a respective bus transaction by function module 13 and buffered by the first microcontroller 41.

In a second phase P2, the states of switching elements of the operator panels 4a and 4b are verified in a respective bus transaction in steps S5 to S8. In particular, in steps S5 and S6, the buttons 56 and 58 of the right operator panel 4b connected via the input/output modules 49 and in the steps S7 and S8 the corresponding operating elements of the left operator panel 4a are verified and buffered in the first microcontroller 41. In a further bus transaction of the serial bus system 47b, a value of the temperature sensor 50 is verified in a step S9 and buffered in the first microcontroller 41.

In a third phase P3, the verified switch positions of the switching elements are transferred back to the corresponding server modules 22a to 22d in steps S1 to S13 in four successive bus transactions.

In a final phase P4, which again comprises four bus transactions, the display elements of the first operator panel 4a and of the second operator panel 4b are finally updated in steps S14 to S17. Here, besides the control signals of the functional modules 13 sampled in the first phase P1, system-specific control signals are additionally considered. For example, error states of the power supplies 15 or of the cooling devices 12 can be signaled via the system management bus 36 to the first microcontroller 41 and buffered there. In the exemplary embodiment, a bit of an 8-bit-wide control value of the four input/output modules 49, which is not required for the transmission of the module-specific control signals, is used for controlling one of the LED displays 62 to 65. Subsequently, the process is restarted in step S1.

In the described embodiment, in each case up to eight bits are combined in a common control data set and transmitted in a serial manner respectively via bus systems 45 and 47a and 47b. Here, the individual steps S1 to S17 are executed successively by the first microcontroller 41 as a bus master, so that no collision occurs during the data transmission via the bus system 45. Since no other bus master is connected to the serial bus systems 45, 47a and 47b, the provision of bus arbitration can be dispensed with. In the described exemplary embodiment, each bus transaction requires a period of 5 ms, so that the entire control loop takes a total of 85 ms. This time interval is sufficiently small to ensure a real-time display of the various display elements or a timely response to key strokes of the operating elements.

In the described exemplary embodiment, the above-described sequential implementation of bus transactions was selected due to simple implementation of the hardware configuration and the control software of the microcontroller 41. If the microcontroller 41 is configured for the simultaneous transmission or reception of data on the different bus systems 45, 47a and 47b, the cycle time can be further shortened. For example, in a first phase, the states of the control signals from the server modules 22 could be verified parallel to the key states of the switching elements of the operator panels 4a and 4b and transferred in a subsequent second phase to the corresponding display elements or server modules 22a to 22d.

### LIST OF REFERENCE NUMERALS

1 Modular computer system
2 Chassis
3 Fastening strap
4 operator panel
5 Group of memory plugins
6 Perforated rail
7 Receiving bay (for functional module)
8 Further receiving bay (for power supply)
9 First circuit board
10 Second circuit board
11 Circuit board connection
12 Cooling device
13 Functional module
14 Memory plugin
15 Power supply
16 Connection structure
17 Module connection
18 (corresponding) connection
19 Copper plate
20 Third circuit board
21 Copper rail
22 Server module
23 Processor
24 Memory bank
25 First configuration
26 Second configuration
27 Third configuration
28 Fourth configuration
31 Chassis interface unit
32 System management module
33 First interface module
34 IPMB bus system
35 Second interface module
36 System management bus
37 Ambient temperature sensor
39 Chassis FRU memory
40 Light path controller
41 First microcontroller (for the operator panels)
42 Second microcontroller (for the flash memory)
43 Flash memory
44 Third microcontroller (for the cooling device)
45 Serial bus system
46 Control circuit
47 Serial bus system
48 Input/output module
49 Input/output module
50 Temperature sensor
51 Input/output connection
52 Bus connection
53 Sub-group of (module-specific) operating elements
54 Sub-group of (module-specific) operating elements
55 Switch-on button
56 Switch-on LED
57 Stand-by LED
58 Identifying button
59 Identifying LED
60 to 65 LED displays
P1 to P4 Phases
S1 to S17 Method steps

1. A modular computer system, comprising
a chassis having a plurality of receiving bays, arranged in the region of a first housing side, for receiving corresponding functional modules, in particular server modules; and
at least one first operator panel arranged on a second housing side, having a plurality of operating elements; wherein
the at least one operator panel is coupled via at least one first serial bus system to at least a first connection of a first receiving bay and a second connection of a second receiving bay;
at least one first sub-group of the operating elements is assigned to the first receiving bay and a second sub-group of the operating elements is assigned to the second receiving bay; and
the modular computer system is configured to transmit module-specific control data via the first serial bus system between the first sub-group of the operating elements and a functional module received in the first receiving bay and between the second sub-group of the operating elements and a functional module received in the second receiving bay.

2. The modular computer system according to claim 1, further comprising at least one microcontroller arranged in the chassis, wherein the microcontroller is configured to control the data exchange of the module-specific control data.

3. The modular computer system according to claim 2, further comprising at least one circuit board arranged inside the chassis for electrically contacting the functional module, in which at least one of the microcontroller the first connection and the second connection are arranged on the at least one circuit board.

4. The modular computer system according to claim 2, wherein
each of the receiving bays of the chassis comprises at least one corresponding connection for electrically contacting a functional module received in the respective receiving bay;
the microcontroller is connected to all connections via the first serial bus system for electrically contacting functional modules received in the receiving bays; and
the microcontroller is configured to subsequently exchange the module-specific control data with functional modules received in different receiving bays via the first serial bus system.

5. The modular computer system according claim 2, in which the microcontroller is connected to the at least one operator panel via at least one second serial bus system and the microcontroller is configured to buffer module-specific control data from functional modules received in at least the first and second receiving bays and to exchange it with the at least one operator panel via the second serial bus system.

6. The modular computer system according to claim 5, comprising a first operator panel and a second operator panel, which are arranged on opposite ends of the second housing side, wherein the microcontroller is connected to the first operator panel via the second serial bus system and connected to the second operator panel via the third serial bus system, and wherein the microcontroller is further configured to buffer the module-specific control data of the functional modules received in at least a third receiving bay and a fourth receiving bay and to exchange it with the second operator panel via the third serial bus system.

7. The modular computer system according to claim 2, in which the microcontroller is connected to at least one administrative component of the modular computer system via at least one system management bus, the at least one operator panel comprises at least one system-specific operating element assigned to the modular computer system as a whole and the microcontroller is configured to exchange system-specific control data with the at least one administrative component via the system management bus, to buffer it and to exchange it with the system-specific operating element.

8. The modular computer system according to claim 1, in which the plurality of operating elements comprises at least one switching element, in particular a button, wherein the modular computer system is configured to verify a switch state of the switching element from the operator panel and forward said state to at least one of the plurality of functional modules.

9. The modular computer system according to claim 1, in which the plurality of operating elements comprises at least one display element, in particular a LED, wherein the modular computer system is configured to verify a state of at least one of the functional modules and to display said state via the display element.

10. A Server module for use in a modular computer system, comprising:
at least one system board for receiving system components;
at least one module connection for electrically contacting a corresponding connection of the modular computer system; and
at least one input/output module having a plurality of parallel input/output connections and a bus connection for a serial bus system;
wherein
the bus connection of the input/output module is electrically connected to the module connection;
the parallel input/output connections are connected to a plurality of module-specific control signals; and
the input/output module is configured to serially transmit the plurality of control signals received and outputted via the parallel input/output connections, respectively, as module-specific control data via the serial bus system.

11. The server module according to claim 10, further comprising at least one firmware component stored in a non-volatile memory of the server module, wherein the firmware component is configured to at least one of provide and verify at least a first subgroup of the plurality of control signals.

12. The server module according to claim 10, further comprising at least one system management module for at least one of administration and monitoring of the server module, wherein the system management module is configured to at least one of provide and verify at least a second subgroup of the plurality of control signals.

13. The server module according to claim 10, wherein the server module is configured to be received in the modular computer system comprising:
a chassis having a plurality of receiving bays, arranged in the region of a first housing side, for receiving corresponding functional modules, in particular server modules; and
at least one first operator panel arranged on a second housing side, having a plurality of operating elements;
wherein
the at least one operator panel is coupled via at least one first serial bus system to at least a first connection of a first receiving bay and a second connection of a second receiving bay;
at least one first sub-group of the operating elements is assigned to the first receiving bay and a second sub-group of the operating elements is assigned to the second receiving bay; and
the modular computer system is configured to transmit module-specific control data via the first serial bus system between the first sub-group of the operating elements and a functional module received in the first receiving bay and between the second sub-group of the operating elements and a functional module received in the second receiving bay.

14. A rack arrangement, comprising:
a rack housing for receiving a plurality of rack plugins in a standardized form factor from a first side of the rack housing;
a chassis received in the rack housing, the chassis having a plurality of receiving bays for receiving corresponding functional modules, in particular server modules; and
at least one first operator panel having a plurality of operating elements;
wherein
the at least one operator panel is coupled via at least one first serial bus system to at least a first connection of a first receiving bay and a second connection of a second receiving bay of the plurality of receiving bays of the chassis;
at least one first sub-group of the operating elements is assigned to the first receiving bay and a second sub-group of the operating elements is assigned to the second receiving bay;
a connection structure of the chassis is configured to transmit module-specific control data via the first serial bus system between the first sub-group of the operating elements and a functional module received in the first receiving bay and between the second sub-group of the operating elements and a functional module received in the second receiving bay; and
the at least one operator panel is arranged in a region of the modular computer system which is accessible from the first side of the rack housing and serves for fastening the modular computer system to the rack housing.

15. The rack arrangement according to claim 14, wherein the connection structure comprises at least one microcontroller arranged in the chassis, wherein the microcontroller is configured to control the data exchange of the module-specific control data.

16. The rack arrangement according to claim 15, wherein the connection structure further comprises at least one circuit board arranged inside the chassis for electrically contacting the functional module received in the first receiving bay and the functional module received in the second receiving bay, in which at least one of the microcontroller the first connection and the second connection are arranged on the at least one circuit board.

17. The rack arrangement according to claim 15, wherein
each of the receiving bays of the chassis comprises at least one corresponding connection for electrically contacting a functional module received in the respective receiving bay;
the microcontroller is connected to all connections via the first serial bus system for electrically contacting functional modules received in the receiving bays; and
the microcontroller is configured to subsequently exchange the module-specific control data with functional modules received in different receiving bays via the first serial bus system.

18. The rack arrangement according to claim 15, in which the microcontroller is connected to the at least one operator panel via at least one second serial bus system and the microcontroller is configured to buffer module-specific control data from functional modules received in at least the first and second receiving bays and to exchange it with the at least one operator panel via the second serial bus system.

19. The rack arrangement according to claim 18, comprising a first operator panel and a second operator panel, which are arranged on opposite ends of the second housing side, wherein the microcontroller is connected to the first operator panel via the second serial bus system and connected to the second operator panel via the third serial bus system, and wherein the microcontroller is further configured to buffer the module-specific control data of the functional modules received in at least a third receiving bay and a fourth receiving bay and to exchange it with the second operator panel via the third serial bus system.

20. The rack arrangement according to claim 18, further comprising at least one server module received in one of the plurality of receiving bays of the chassis, each of the at least on server module comprising:
at least one system board for receiving system components;
at least one module connection for electrically contacting a corresponding connection of the modular computer system; and
at least one input/output module having a plurality of parallel input/output connections and a bus connection for a serial bus system;
wherein
the bus connection of the input/output module is electrically connected to the module connection;
the parallel input/output connections are connected to a plurality of module-specific control signals; and
the input/output module is configured to serially transmit the plurality of control signals received and outputted via the parallel input/output connections, respectively, as module-specific control data via the serial bus system.
